(19) United States
(12) Patent Application Publication
(10) Pub. No.: US 2016/0307929 A1
(43) Pub. Date: Oct. 20, 2016

(54) MANUFACTURE METHOD AND STRUCTURE OF TFT BACKPLATE APPLICABLE TO AMOLED

(71) Applicant: Shenzhen China Star Optoelectronics Technology Co. Ltd., Shenzhen City (CN)

(72) Inventor: Zhandong ZHANG, Shenzhen City (CN)

(73) Assignee: Wuhan China Star Optoelectronics Technology Co., Ltd., Wuhan City (CN)

(21) Appl. No.: 14/655,723

(22) PCT Filed: May 13, 2015
(86) PCT No.: PCT/CN2015/078866

§ 371 Date: Jun. 26, 2015

(30) Foreign Application Priority Data
Jan. 20, 2015 (CN) 201510028232.2

(51) Int. Cl. H01L 27/12; H01L 21/265; H01L 29/786; H01L 21/28; H01L 21/285; H01L 21/02; H01L 29/66

(52) U.S. Cl. CPC H01L 27/1222; H01L 27/1274; H01L 21/02532; H01L 21/02592; H01L 21/02675; H01L 21/26506; H01L 29/66757; H01L 21/02271; H01L 21/02164; H01L 21/0217; H01L 27/1218; H01L 21/28079; H01L 27/1248; H01L 21/2855; H01L 21/28568; H01L 29/78675; H01L 27/3262

(57) ABSTRACT

The present invention provides a manufacture method and a structure of a TFT backplate applicable to an AMOLED. The method comprises: step 1, providing a substrate (10) and deposing a buffer layer (20); step 2, sequentially forming an active layer (30) and a gate isolation layer (40) on the buffer layer (20); step 3, patterning the gate isolation layer (40) to form a concave part (401); step 4, forming a gate (50) of the switch thin film transistor and a gate (60) of the drive thin film transistor on the gate isolation layer, and the gate (50) of the switch thin film transistor is in the concave part (401); step 5, deposing an interlayer insulation layer (70). The method simplifies the manufacture process of the TFT backplate and increases the subthreshold swing of the drive thin film transistor by manufacturing a single layer gate isolation layer with height difference to raise the gray scale switch and control performance of the AMOLED panel.

### FIELD OF THE INVENTION

The present invention relates to a display technology field, and more particularly to a manufacture method and a structure of a TFT backplate applicable to an AMOLED.

### BACKGROUND OF THE INVENTION

The flat panel display elements possess many merits of thin frame, power saving, no radiation, etc. and have been widely used. The present flat panel display elements at present mainly comprise the Liquid Crystal Display (LCD) and the Organic Light Emitting Display (OLED).

An OLED possesses many outstanding properties of self-illumination, no requirement of backlight, high contrast, ultra-thin, wide view angle, fast response, applicability of flexible panel, wide range of working temperature, simpler structure and process. The OLED is considered as next generation flat panel display technology.

The OLED can be categorized as Passive matrix OLED (PMOLED) and (Active matrix OLED) AMOLED according to their driving types. The AMOLED possesses characters if faster response, higher contrast ratio, wider view angle, etc. and generally comprises the substrate, the Thin Film Transistor (TFT) formed on the substrate and the organic light emitting diode formed on the Thin Film Transistor. The Thin Film Transistor drives the organic light emitting diode to light and thus to show the corresponding pictures. Specifically, the Thin Film Transistor at least comprises one Drive TFT and one Switch TFT. The activation and deactivation of the drive TFT is controlled by the switch TFT. The organic light emitting diode is driven to light by the current generated as the drive TFT is in saturated condition and the panel gray scale control is realized by inputting different gray scale voltages to the drive TFT for generating the different driving currents. The sub-threshold swing (S.S.) of the drive TFT directly influences the gray scale switch performance of the display panel.

The sub-threshold swing of the drive TFT is determined by the size of the gate capacitor, and the size of the gate capacitor depends on the thickness of the gate isolation layer. Therefore, the sub-threshold swing of the drive TFT can be raised to promote the gray scale switch performance of the display panel by increasing the thickness of the gate isolation layer.

Please refer to FIG. 1. A structure of a TFT backplate applicable to an AMOLED according to prior art comprises a switch TFT T1 and a drive TFT T2, wherein the gate isolation layer is a double layer structure, comprising a first gate isolation layer 4 and a second gate isolation layer 6. By adjusting the thickness of the second gate isolation layer 6, the effect of increasing the sub-threshold swing of the drive TFT T2 can be achieved. The manufacture procedure of the TFT backplate applicable to an AMOLED according to prior art is: first, deposing a buffer layer 2 on the substrate 1, and next, deposing an amorphous silicon layer (a-Si) and converting the amorphous silicon layer to be a polysilicon layer (poly-Si) by an Excimer Laser Annealing (ELA), and then, patterning the polysilicon layer and ion doping the same to form an active layer 3 having an active layer 31 of the switch thin film transistor and the active layer 32 of the drive thin film transistor. By CVD process, a first gate isolation layer 4 is deposed on the active layer 3 and the buffer layer 2. By sputter and photolithography processes, the gate 5 of the switch thin film transistor is formed. By CVD process, a second gate isolation layer 6 is deposed on the gate 5 of the switch thin film transistor and the first gate isolation layer 4. By sputter and photolithography processes, a gate 7 of the drive thin film transistor is formed. Then, an interlayer insulation layer 8, a source/a drain 9 are sequentially formed to accomplish the manufacture of the TFT backplate. In the manufacture method, two gate isolation layers are essential to deposed to increase the sub-threshold swing of the drive TFT T2. The manufacture process is more complicated and the manufacture efficiency is lower.

### SUMMARY OF THE INVENTION

An objective of the present invention is to provide a manufacture method applicable to a TFT backplate of AMOLED, and the method simplifies the manufacture process of the TFT backplate and reduce the number of the manufacture processes to realize the objective of increasing the subthreshold swing of the drive thin film transistor with fewer manufacture processes to raise the gray scale switch and control performance of the AMOLED panel.

Another objective of the present invention is to provide a structure of a TFT backplate applicable to an AMOLED, capable of increasing the subthreshold swing of the drive thin film transistor and raising the gray scale switch and control performance of the AMOLED panel. Meanwhile, the manufacture process is simple.

For realizing the aforesaid objectives, the present invention provides a manufacture method applicable to a TFT backplate of AMOLED, comprising steps of:

step 1, providing a substrate and deposing a buffer layer on the substrate;

step 2, forming an active layer on the buffer layer and deposing a gate isolation layer on the active layer and the buffer layer;

the active layer comprises an active layer of a switch thin film transistor and an active layer of a drive thin film transistor;

step 3, patterning the gate isolation layer to form a concave part on the active layer of the switch thin film transistor, and a thickness of the gate isolation layer on the active layer of the switch thin film transistor is smaller than a thickness of the gate isolation layer on the active layer of the drive thin film transistor;

step 4, forming a gate of the switch thin film transistor and a gate of the drive thin film transistor on the gate isolation layer by sputter and photolithography processes;

the gate of the switch thin film transistor is located on the concave part;

step 5, deposing an interlayer insulation layer on the gate of the switch thin film transistor, the gate of the drive thin film transistor and the gate isolation layer.

The manufacture method of the TFT backplate applicable to the AMOLED further comprises a step 6, forming a source/a drain of the switch thin film transistor and a source/a drain of the driving thin film transistor in corresponding areas of the active layer of the switch thin film transistor and the active layer of the drive thin film transistor.

The step 2 comprises:

step 21, deposing an amorphous silicon layer on the buffer layer;

step 22, converting the amorphous silicon layer to be a polysilicon layer by an Excimer Laser Annealing process;

step 23, patterning the polysilicon layer and implementing ion doping process to form the active layer of the switch thin film transistor and the active layer of the drive thin film transistor;

step 24, forming the gate isolation layer on the active layer and the buffer layer.

In the step 24, the gate isolation layer is formed on the active layer and the buffer layer by utilizing a chemical vapor deposition process.

The substrate is a transparent substrate; the buffer layer comprises one a silicon oxide layer, a silicon nitride or a combination thereof; the gate isolation layer comprises a silicon oxide layer, a silicon nitride or a combination thereof.

In the step 3, the gate isolation layer is patterned by photolithography process to form the concave part on the active layer of the switch thin film transistor.

Material of the gate of the switch thin film transistor and the gate of the drive thin film transistor is molybdenum; the interlayer insulation layer comprises one a silicon oxide layer, a silicon nitride or a combination thereof; the source/the drain of the switch thin film transistor and the source/the drain of the driving thin film transistor contact the corresponding areas of the active layer of the switch thin film transistor and the active layer of the drive thin film transistor through via holes formed in the interlayer insulation layer and the gate isolation layer.

The present invention further provides a manufacture method of a TFT backplate applicable to an AMOLED, comprising steps of:

step 1, providing a substrate and deposing a buffer layer on the substrate;

step 2, forming an active layer on the buffer layer and deposing a gate isolation layer on the active layer and the buffer layer;

the active layer comprises an active layer of a switch thin film transistor and an active layer of a drive thin film transistor;

step 3, patterning the gate isolation layer to form a concave part on the active layer of the switch thin film transistor, and a thickness of the gate isolation layer on the active layer of the switch thin film transistor is smaller than a thickness of the gate isolation layer on the active layer of the drive thin film transistor;

step 4, forming a gate of the switch thin film transistor and a gate of the drive thin film transistor on the gate isolation layer by sputter and photolithography processes;

the gate of the switch thin film transistor is located on the concave part;

step 5, deposing an interlayer insulation layer on the gate of the switch thin film transistor, the gate of the drive thin film transistor and the gate isolation layer;

step 6, forming a source/a drain of the switch thin film transistor and a source/a drain of the driving thin film transistor in corresponding areas of the active layer of the switch thin film transistor and the active layer of the drive thin film transistor;

wherein the step 2 comprises:

step 21, deposing an amorphous silicon layer on the buffer layer;

step 22, converting the amorphous silicon layer to be a polysilicon layer by an Excimer Laser Annealing process;

step 23, patterning the polysilicon layer and implementing ion doping process to form the active layer of the switch thin film transistor and the active layer of the drive thin film transistor;

step 24, forming the gate isolation layer on the active layer and the buffer layer.

The present invention further provides a structure of a TFT backplate applicable to an AMOLED, comprising:

a substrate;

a buffer layer located on the substrate;

an active layer located on the buffer layer, and the active layer comprises an active layer of a switch thin film transistor and an active layer of a drive thin film transistor;

a gate isolation layer located on the active layer and the buffer layer, and the gate isolation layer comprises a concave part corresponding to a location of the active layer of the switch thin film transistor;

a gate of the switch thin film transistor located on the concave part and a gate of the drive thin film transistor on the active layer of the drive thin film transistor and located on the gate isolation layer;

an interlayer insulation layer located on the gate of the switch thin film transistor, the gate of the drive thin film transistor and the gate isolation layer.

The structure of the TFT backplate applicable to the AMOLED further comprises a source/a drain of the switch thin film transistor and a source/a drain of the driving thin film transistor located in corresponding areas of the active layer of the switch thin film transistor and the active layer of the drive thin film transistor.

The substrate is a transparent substrate; material of the gate of the switch thin film transistor and the gate of the drive thin film transistor is molybdenum; the buffer layer comprises one a silicon oxide layer, a silicon nitride or a combination thereof; the gate isolation layer comprises a silicon oxide layer, a silicon nitride or a combination thereof; the interlayer insulation layer comprises one a silicon oxide layer, a silicon nitride or a combination thereof; the source/the drain of the switch thin film transistor and the source/the drain of the driving thin film transistor contact the corresponding areas of the active layer of the switch thin film transistor and the active layer of the drive thin film transistor through via holes formed in the interlayer insulation layer and the gate isolation layer.

The benefits of the present invention are: the manufacture method of the TFT backplate applicable to the AMOLED provided by the present invention, by forming the concave part at the gate isolation layer by photolithography process to form the gate isolation layer with the thickness difference, wherein the part of which the thickness is smaller is employed to be the gate isolation layer of the switch TFT, and the part of which the thickness is larger is employed to be the gate isolation layer of the drive TFT, simplifies the manufacture process of the TFT backplate and reduces the number of the manufacture processes. Under the premise of not changing the thickness of the gate isolation layer of the switch TFT, the thickness of the gate isolation layer of the drive TFT is increased with fewer manufacture processes. Accordingly, the subthreshold swing of the drive TFT is increased to raise the gray scale switch and control performance of the AMOLED panel. The structure of the TFT backplate applicable to the AMOLED provided by the present invention, by locating the concave part at the gate isolation layer to make a single layer gate isolation layer with thickness difference, wherein the part of which the thickness is smaller is employed to be the gate isolation layer of the switch TFT, and the part of which the thickness is larger is employed to be the gate isolation layer of the drive TFT, can increase the subthreshold swing of the drive TFT to raise the gray scale switch and control performance of the AMOLED panel. Meanwhile, the manufacture process is simple.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a sectional diagram of a structure of a TFT backplate applicable to an AMOLED according to prior art;

FIG. 2 is a flowchart of a manufacture method of a TFT backplate applicable to an AMOLED according to the present invention;

FIG. 3 is a diagram of step 1 of the manufacture method of the TFT backplate applicable to the AMOLED according to the present invention;

FIG. 4 is a diagram of step 2 of the manufacture method of the TFT backplate applicable to the AMOLED according to the present invention;

FIG. 5 is a diagram of step 3 of the manufacture method of the TFT backplate applicable to the AMOLED according to the present invention;

FIG. 6 is a diagram of step 4 of the manufacture method of the TFT backplate applicable to the AMOLED according to the present invention;

FIG. 7 is a diagram of step 5 of the manufacture method of the TFT backplate applicable to the AMOLED according to the present invention;

FIG. 8 is a diagram of step 6 of the manufacture method of the TFT backplate applicable to the AMOLED according to the present invention and also a sectional diagram of a structure of the TFT backplate applicable to an AMOLED according to the present invention.

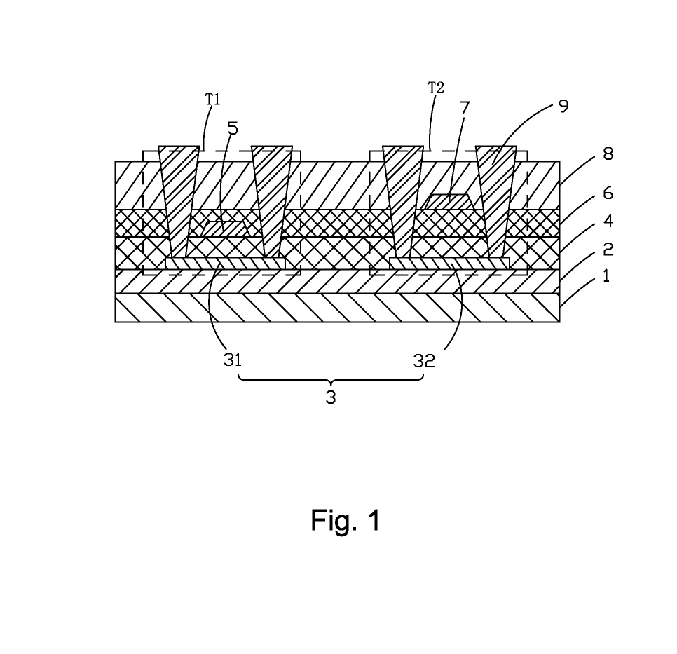

### DETAILED DESCRIPTION OF PREFERRED EMBODIMENTS

For better explaining the technical solution and the effect of the present invention, the present invention will be further described in detail with the accompanying drawings and the specific embodiments.

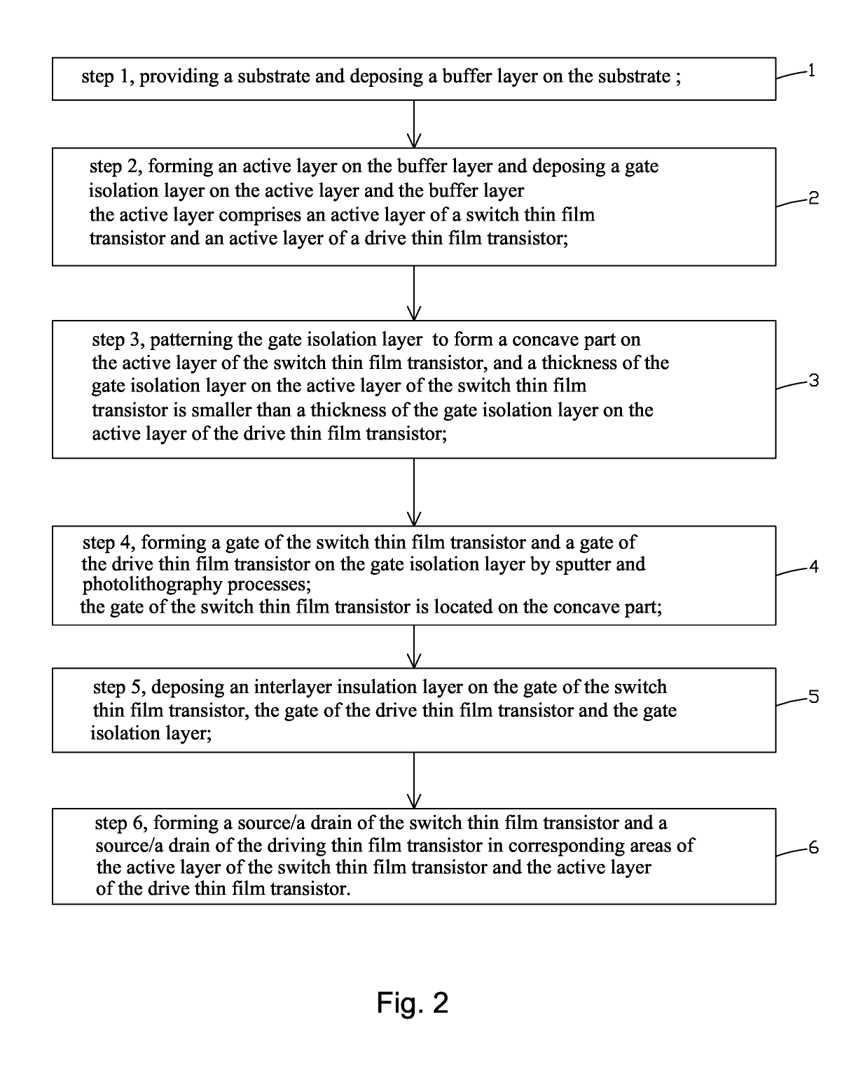

Please refer to FIG. 2. The present invention provides a manufacture method of a TFT backplate applicable to an AMOLED, comprising steps of:

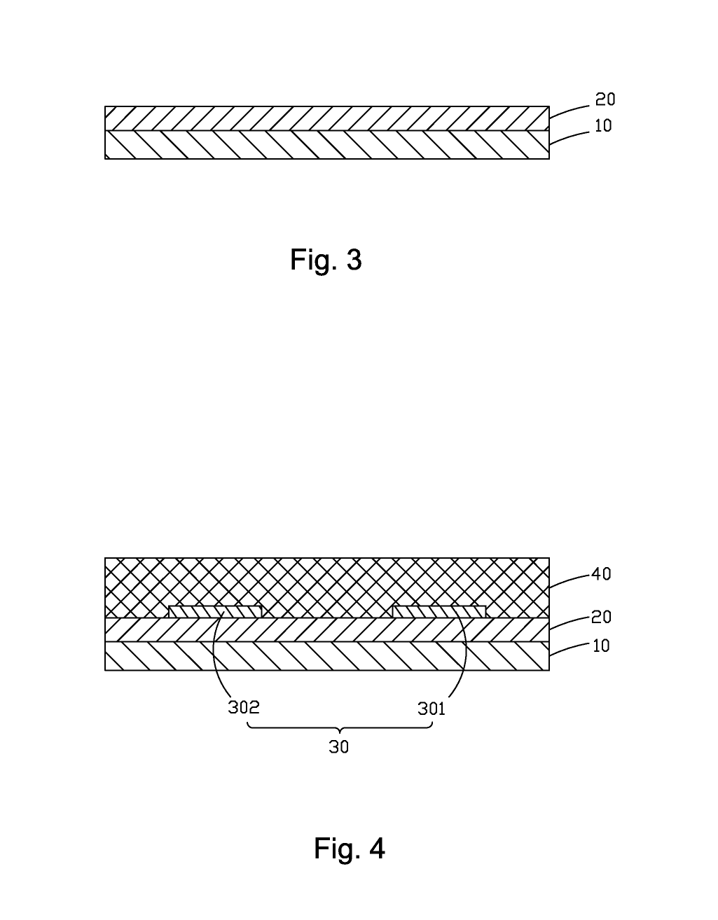

step 1, as shown in FIG. 3, providing a substrate 10 and deposing a buffer layer 20 on the substrate 10.

Specifically, the substrate 10 is a transparent substrate. Preferably, the substrate 10 is a glass substrate. The buffer layer 20 comprises one a silicon oxide layer, a silicon nitride or a combination thereof.

step 2, as shown in FIG. 4, forming an active layer 30 on the buffer layer 20 and deposing a gate isolation layer 40 on the active layer 30 and the buffer layer 20.

The active layer 30 comprises an active layer 302 of a switch thin film transistor and an active layer 301 of a drive thin film transistor. The gate isolation layer 40 comprises one a silicon oxide layer, a silicon nitride or a combination thereof.

Specifically, the step 2 further comprises steps of:

step 21, deposing an amorphous silicon layer on the buffer layer 20;

step 22, converting the amorphous silicon layer to be a polysilicon layer by an Excimer Laser Annealing process;

step 23, patterning the polysilicon layer and implementing ion doping process, of which the N type or the P type ions are selected according to the types of the manufactured thin film transistors to form the active layer 30 comprising the active layer 302 of the switch thin film transistor and the active layer 301 of the drive thin film transistor;

step 24, forming the gate isolation layer 40 on the active layer 30 and the buffer layer 20 by utilizing a chemical vapor deposition process, and the active layer 302 of the switch thin film transistor and the active layer 301 of the drive thin film transistor are separated by the gate isolation layer 40.

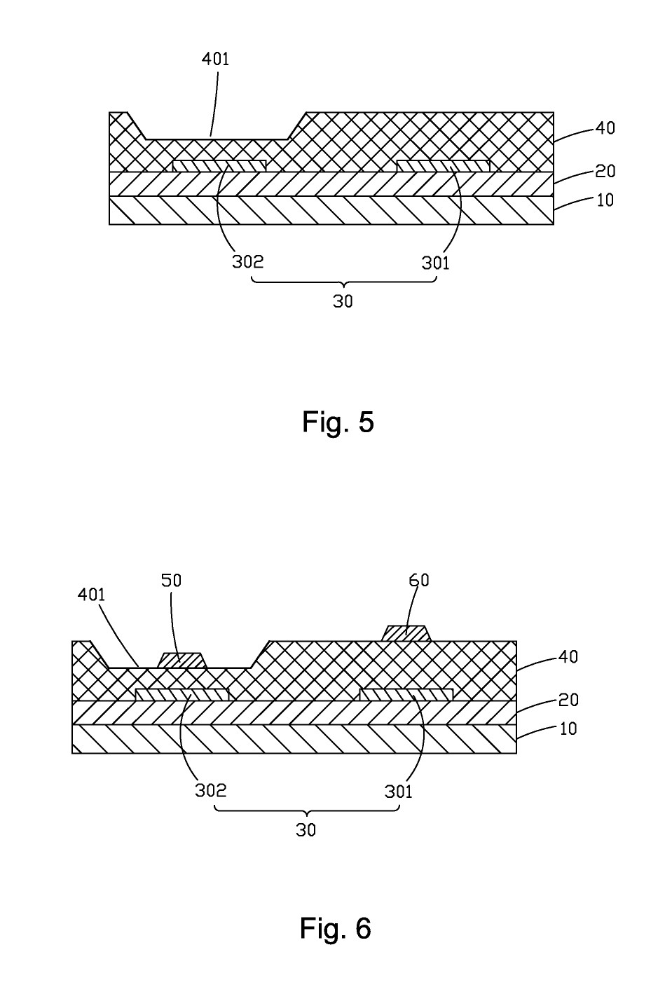

step 3, as shown in FIG. 5, patterning the gate isolation layer 40 to form a concave part 401 on the active layer 302 of the switch thin film transistor, and a thickness of the gate isolation layer 40 on the active layer 302 of the switch thin film transistor is smaller than a thickness of the gate isolation layer 40 on the active layer 301 of the drive thin film transistor.

Specifically, in the step 3, the gate isolation layer 40 is patterned by photolithography process; first, a layer of photo glue is coated on the gate isolation layer 40, and then the photo glue is irradiated by the light passing through the mask to expose the photo glue, and then the partial photo glue is removed by stripper to define the desired pattern for forming the concave part 401, and finally, etching is implemented according to the pattern defined by the photo glue to obtain the concave part 401 and the gate isolation layer 40 comprising the concave part 401.

Significantly, with the existence of the concave part 401, a thickness of the gate isolation layer 40 corresponding to the switch thin film transistor T10 is smaller than a thickness of the gate isolation layer 40 corresponding to the drive thin film transistor T20. In the step 3, the thickness difference is formed at the single gate isolation layer 40. Compared with the method of prior arts, of which two gate isolation layers are manufactured one after another, the step simplifies the manufacture process and reduces the number of the manufacture processes. as ensuring not to change the thickness of the gate isolation layer of the switch TFT T10, meanwhile, the thickness of the gate isolation layer of the drive TFT T20 is increased to raise the subthreshold swing of the drive TFT T20 and the gray scale switch and control performance of the AMOLED panel.

step 4, as shown in FIG. 6, forming a gate 50 of the switch thin film transistor and a gate 60 of the drive thin film transistor on the gate isolation layer 40 by sputter and photolithography processes.

Specifically, the gate 50 of the switch thin film transistor is located on the concave part 401 and a gate 60 of the drive thin film transistor is on the active layer 301 of the drive thin film transistor and located on the gate isolation layer 40. Material of the gate 50 of the switch thin film transistor and the gate 60 of the drive thin film transistor is molybdenum (Mo). Compared with prior arts, the gate 50 of the switch thin film transistor and the gate 60 of the drive thin film transistor are formed at the same time, which simplifies the manufacture process and reduces the number of the manufacture processes in advance to raise the production efficiency.

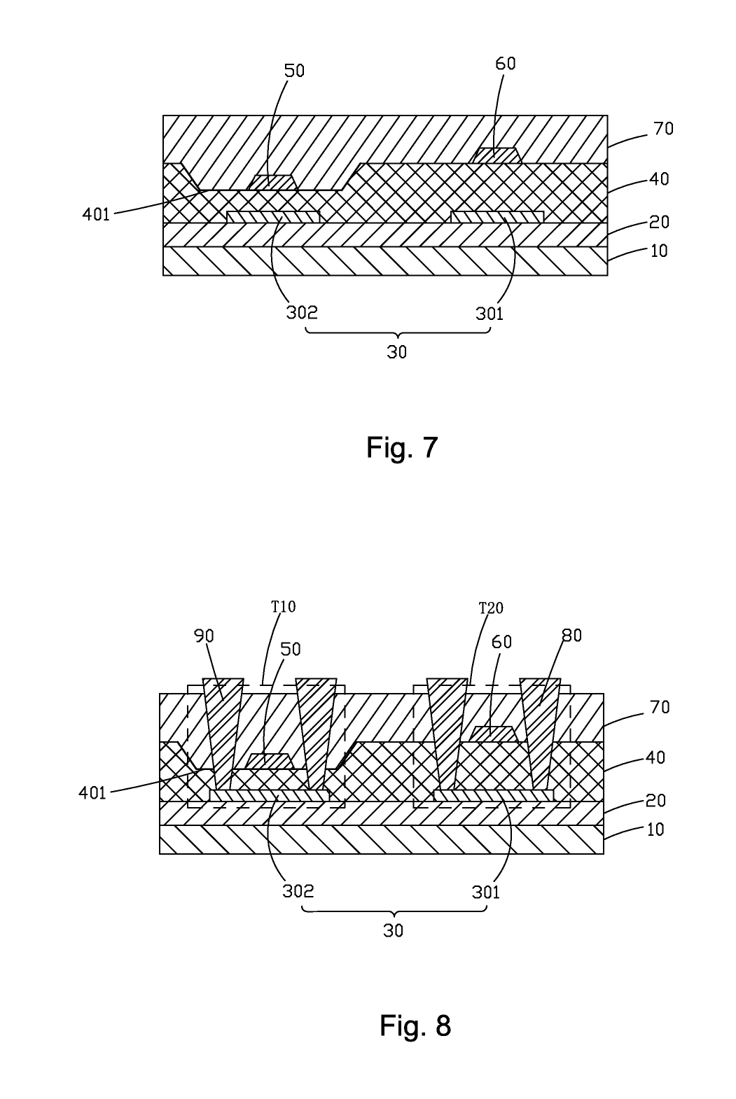

step 5, as shown in FIG. 7, deposing an interlayer insulation layer 70 on the gate 50 of the switch thin film transistor, the gate of the drive thin film transistor 60 and the gate isolation layer 40.

Specifically, in the step 5, the interlayer insulation layer 70 comprises one a silicon oxide layer, a silicon nitride or a combination thereof.

Furthermore, the manufacture method of the TFT backplate applicable to the AMOLED further comprises a step 6, as shown in FIG. 8, forming a source/a drain 90 of the switch thin film transistor and a source/a drain 80 of the driving thin film transistor in corresponding areas of the active layer 302 of the switch thin film transistor and the active layer 301 of the drive thin film transistor.

Specifically, both the source/the drain 90 of the switch thin film transistor and the source/the drain 80 of the driving thin film transistor contact the corresponding areas of the active layer 302 of the switch thin film transistor and the active layer 301 of the drive thin film transistor through via holes formed in the interlayer insulation layer 70 and the gate isolation layer 40.

Please refer to FIG. 8. The present invention further provides a structure of a TFT backplate applicable to an AMOLED, comprising:

a substrate 10;

a buffer layer 20 located on the substrate 10;

an active layer 30 located on the buffer layer 20, and the active layer 30 comprises an active layer 302 of a switch thin film transistor and an active layer 301 of a drive thin film transistor;

a gate isolation layer 40 located on the active layer 30 and the buffer layer 20, and the gate isolation layer 40 comprises a concave part 401 corresponding to a location of the active layer 302 of the switch thin film transistor;

a gate 50 of the switch thin film transistor located on the concave part 401 and a gate 60 of the drive thin film transistor on the active layer 301 of the drive thin film transistor and located on the gate isolation layer 40;

an interlayer insulation layer 70 located on the gate 50 of the switch thin film transistor, the gate of the drive thin film transistor 60 and the gate isolation layer 40.

Furthermore, the structure of the TFT backplate applicable to the AMOLED further comprises a source/a drain 90 of the switch thin film transistor and a source/a drain 80 of the driving thin film transistor located in corresponding areas of the active layer 302 of the switch thin film transistor and the active layer 301 of the drive thin film transistor.

Specifically, the substrate 10 is a transparent substrate. Preferably, the substrate 10 is a glass substrate. The buffer layer 20 comprises one a silicon oxide layer, a silicon nitride or a combination thereof. The gate isolation layer 40 comprises one a silicon oxide layer, a silicon nitride or a combination thereof. Material of the gate 50 of the switch thin film transistor and the gate 60 of the drive thin film transistor is molybdenum. The interlayer insulation layer 70 comprises one a silicon oxide layer, a silicon nitride or a combination thereof. Specifically, both the source/the drain 90 of the switch thin film transistor and the source/the drain 80 of the driving thin film transistor contact the corresponding areas of the active layer 302 of the switch thin film transistor and the active layer 301 of the drive thin film transistor through via holes located in the interlayer insulation layer 70 and the gate isolation layer 40 to form the switch thin film transistor T10 and the driving thin film transistor T20.

The structure of the TFT backplate applicable to the AMOLED, by locating the concave part 401 at the gate isolation layer 40, makes the single layer gate isolation layer 40 with thickness difference, wherein the part of which the thickness is smaller is employed to be the gate isolation layer of the switch TFT T10, and the part of which the thickness is larger is employed to be the gate isolation layer of the drive TFT T20. Compared with prior arts, the subthreshold swing of the drive TFT T20 can be increased to raise the gray scale switch and control performance of the AMOLED panel on one hand. On the other hand, merely one gate isolation layer 40 has to be manufactured, and the gate 50 of the switch thin film transistor and the gate 60 of the drive thin film transistor can be formed in one manufacture process at the same time. The manufacture process is simple and the procedure of the manufacture can be simplified.

In conclusion, the manufacture method of the TFT backplate applicable to the AMOLED provided by the present invention, by forming the concave part at the gate isolation layer by photolithography process to form the gate isolation layer with the thickness difference, wherein the part of which the thickness is smaller is employed to be the gate isolation layer of the switch TFT, and the part of which the thickness is larger is employed to be the gate isolation layer of the drive TFT, simplifies the manufacture process of the TFT backplate and reduces the number of the manufacture processes. Under the premise of not changing the thickness of the gate isolation layer of the switch TFT, the thickness of the gate isolation layer of the drive TFT is increased with fewer manufacture processes. Accordingly, the subthreshold swing of the drive TFT is increased to raise the gray scale switch and control performance of the AMOLED panel. The structure of the TFT backplate applicable to the AMOLED according to the present invention, by locating the concave part at the gate isolation layer to make a single layer gate isolation layer with thickness difference, wherein the part of which the thickness is smaller is employed to be the gate isolation layer of the switch TFT, and the part of which the thickness is larger is employed to be the gate isolation layer of the drive TFT, can increase the subthreshold swing of the drive TFT to raise the gray scale switch and control performance of the AMOLED panel. Meanwhile, the manufacture process is simple.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A manufacture method of a TFT backplate applicable to an AMOLED, comprising steps of:
step 1, providing a substrate and deposing a buffer layer on the substrate;
step 2, forming an active layer on the buffer layer and deposing a gate isolation layer on the active layer and the buffer layer;
the active layer comprises an active layer of a switch thin film transistor and an active layer of a drive thin film transistor;
step 3, patterning the gate isolation layer to form a concave part on the active layer of the switch thin film transistor, and a thickness of the gate isolation layer on the active layer of the switch thin film transistor is smaller than a thickness of the gate isolation layer on the active layer of the drive thin film transistor;
step 4, forming a gate of the switch thin film transistor and a gate of the drive thin film transistor on the gate isolation layer by sputter and photolithography processes;
the gate of the switch thin film transistor is located on the concave part;
step 5, deposing an interlayer insulation layer on the gate of the switch thin film transistor, the gate of the drive thin film transistor and the gate isolation layer.

2. The manufacture method of the TFT backplate applicable to the AMOLED according to claim 1, further comprising a step 6, forming a source/a drain of the switch thin film transistor and a source/a drain of the driving thin film transistor in corresponding areas of the active layer of the switch thin film transistor and the active layer of the drive thin film transistor.

3. The manufacture method of the TFT backplate applicable to the AMOLED according to claim 1, wherein the step 2 comprises:
step 21, deposing an amorphous silicon layer on the buffer layer;
step 22, converting the amorphous silicon layer to be a polysilicon layer by an Excimer Laser Annealing process;
step 23, patterning the polysilicon layer and implementing ion doping process to form the active layer of the switch thin film transistor and the active layer of the drive thin film transistor;
step 24, forming the gate isolation layer on the active layer and the buffer layer.

4. The manufacture method of the TFT backplate applicable to the AMOLED according to claim 3, wherein in the step 24, the gate isolation layer is formed on the active layer and the buffer layer by utilizing a chemical vapor deposition process.

5. The manufacture method of the TFT backplate applicable to the AMOLED according to claim 1, wherein the substrate is a transparent substrate; the buffer layer comprises one a silicon oxide layer, a silicon nitride or a combination thereof; the gate isolation layer comprises a silicon oxide layer, a silicon nitride or a combination thereof.

6. The manufacture method of the TFT backplate applicable to the AMOLED according to claim 1, wherein in the step 3, the gate isolation layer is patterned by photolithography process to form the concave part on the active layer of the switch thin film transistor.

7. The manufacture method applicable to the TFT backplate of AMOLED according to claim 2, wherein material of the gate of the switch thin film transistor and the gate of the drive thin film transistor is molybdenum; the interlayer insulation layer comprises one a silicon oxide layer, a silicon nitride or a combination thereof; the source/the drain of the switch thin film transistor and the source/the drain of the driving thin film transistor contact the corresponding areas of the active layer of the switch thin film transistor and the active layer of the drive thin film transistor through via holes formed in the interlayer insulation layer and the gate isolation layer.

8. A manufacture method of a TFT backplate applicable to an AMOLED, comprising steps of:
step 1, providing a substrate and deposing a buffer layer on the substrate;
step 2, forming an active layer on the buffer layer and deposing a gate isolation layer on the active layer and the buffer layer;
the active layer comprises an active layer of a switch thin film transistor and an active layer of a drive thin film transistor;
step 3, patterning the gate isolation layer to form a concave part on the active layer of the switch thin film transistor, and a thickness of the gate isolation layer on the active layer of the switch thin film transistor is smaller than a thickness of the gate isolation layer on the active layer of the drive thin film transistor;
step 4, forming a gate of the switch thin film transistor and a gate of the drive thin film transistor on the gate isolation layer by sputter and photolithography processes;
the gate of the switch thin film transistor is located on the concave part;
step 5, deposing an interlayer insulation layer on the gate of the switch thin film transistor, the gate of the drive thin film transistor and the gate isolation layer;
step 6, forming a source/a drain of the switch thin film transistor and a source/a drain of the driving thin film transistor in corresponding areas of the active layer of the switch thin film transistor and the active layer of the drive thin film transistor;
wherein the step 2 comprises:
step 21, deposing an amorphous silicon layer on the buffer layer;
step 22, converting the amorphous silicon layer to be a polysilicon layer by an Excimer Laser Annealing process;
step 23, patterning the polysilicon layer and implementing ion doping process to form the active layer of the switch thin film transistor and the active layer of the drive thin film transistor;
step 24, forming the gate isolation layer on the active layer and the buffer layer.

9. The manufacture method applicable to the TFT backplate of AMOLED according to claim 8, wherein in the step 24, the gate isolation layer is formed on the active layer and the buffer layer by utilizing a chemical vapor deposition process.

10. The manufacture method applicable to the TFT backplate of AMOLED according to claim 8, wherein the substrate is a transparent substrate; the buffer layer comprises one a silicon oxide layer, a silicon nitride or a combination thereof; the gate isolation layer comprises a silicon oxide layer, a silicon nitride or a combination thereof.

11. The manufacture method applicable to the TFT backplate of AMOLED according to claim 8, wherein in the step 3, the gate isolation layer is patterned by photolithography process to form the concave part on the active layer of the switch thin film transistor.

12. The manufacture method applicable to the TFT backplate of AMOLED according to claim 8, wherein material of the gate of the switch thin film transistor and the gate of the drive thin film transistor is molybdenum; the interlayer insulation layer comprises one a silicon oxide layer, a silicon nitride or a combination thereof; the source/the drain of the switch thin film transistor and the source/the drain of the driving thin film transistor contact the corresponding areas of the active layer of the switch thin film transistor and the active layer of the drive thin film transistor through via holes formed in the interlayer insulation layer and the gate isolation layer.

13. A structure of a TFT backplate applicable to an AMOLED, comprising:
a substrate;
a buffer layer located on the substrate;
an active layer located on the buffer layer, and the active layer comprises an active layer of a switch thin film transistor and an active layer of a drive thin film transistor;
a gate isolation layer located on the active layer and the buffer layer, and the gate isolation layer comprises a concave part corresponding to a location of the active layer of the switch thin film transistor;
a gate of the switch thin film transistor located on the concave part and a gate of the drive thin film transistor on the active layer of the drive thin film transistor and located on the gate isolation layer;
an interlayer insulation layer located on the gate of the switch thin film transistor, the gate of the drive thin film transistor and the gate isolation layer.

14. The structure of the TFT backplate applicable to the AMOLED according to claim 13, further comprising a source/a drain of the switch thin film transistor and a source/a drain of the driving thin film transistor located in corresponding areas of the active layer of the switch thin film transistor and the active layer of the drive thin film transistor.

15. The structure of the TFT backplate applicable to the AMOLED according to claim 14, wherein the substrate is a transparent substrate; material of the gate of the switch thin film transistor and the gate of the drive thin film transistor is molybdenum; the buffer layer comprises one a silicon oxide layer, a silicon nitride or a combination thereof; the gate isolation layer comprises a silicon oxide layer, a silicon nitride or a combination thereof; the interlayer insulation layer comprises one a silicon oxide layer, a silicon nitride or a combination thereof; the source/the drain of the switch thin film transistor and the source/the drain of the driving thin film transistor contact the corresponding areas of the active layer of the switch thin film transistor and the active layer of the drive thin film transistor through via holes formed in the interlayer insulation layer and the gate isolation layer.
